(19) United States
(12) Patent Application Publication
(10) Pub. No.: US 2006/0285304 A1
(43) Pub. Date: Dec. 21, 2006

(54) Computer enclosure with locking top cover

(75) Inventors: Yun-Lung Chen, Tu-Cheng (TW); Wen-Yu Zhang, Shenzhen (CN); Jun Tang, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/314,599

(22) Filed: Dec. 21, 2005

(30) Foreign Application Priority Data
Jun. 18, 2005 (CN) 200520060384.2

(51) Int. Cl. H05K 5/00

(52) U.S. Cl. 361/752

(57) ABSTRACT

A computer enclosure includes a chassis (30), a top cover (10) for covering the chassis, and a locking member (50). A side wall (33) is bent from the chassis. A stop portion (342) is horizontally formed on the side wall. The locking member is slidably attached to the top cover. A locking portion (58) is vertically extending from the locking member corresponding to the stop portion of the chassis. A slope (582) is formed on the locking portion, for abutting against the stop portion of the chassis. A resilient member (70) is connected to the locking member and the top cover, for allowing the locking member to be offset, thereby the locking member riding over the stop portion and engaging therewith.

### BACKGROUND OF THE INVENTION

1. Field of the Invention

The present invention relates to computer enclosures, and more particularly to a computer enclosure with a locking device which allows easy installation and removal of a top cover.

2. General Background

A conventional computer enclosure includes a side panel releasably attached thereto for covering an opening defined in a side wall thereof. The side panel has a first edge from which a perpendicular flange extends. Anchoring tabs perpendicularly extend from the flange. A step is formed on a corresponding edge of the opening with slots defined therein to receive the anchoring tabs with the flange abutting against the step thereby effectively eliminating electromagnetic radiation emitted through the opening. A plurality of locking tabs is formed on an opposite second edge of the side panel. A plurality of cutouts is defined in a rear wall of the enclosure corresponding to the locking tabs. A locking rod movably attached to a rear wall defines a plurality of openings corresponding to the cutouts whereby the locking tabs are allowed to extend through both the cutouts of the enclosure and the openings of the locking rod when the locking rod is in an unlocked position. When the locking rod is moved to a locked position, edges of the openings of the locking rod engage with notches defined in the locking tabs of the side panel thereby securing the side panel in position. A biasing spring is arranged between the locking rod and the enclosure for biasing the locking rod in the locked position. A handle is formed on the locking rod for manually moving the locking rod.

In removal of the side panel from the computer enclosure, the locking rod is urged by one hand thereby releasing the side panel. The side panel is then taken away from the computer enclosure by the other hand. However, it is still inconvenient to remove the top cover from the computer enclosure.

What is needed, therefore, is to provide a computer enclosure having a locking device, which allows convenient assembly and removal of a top cover from the computer chassis.

### SUMMARY

A computer enclosure includes a chassis, a top cover for covering the chassis, and a locking member. A side wall is bent from the chassis. A stop portion is horizontally formed on the side wall. The locking member is slidably attached to the top cover. A locking portion is vertically extending from the locking member corresponding to the stop portion of the chassis. A slope is formed on the locking portion, for abutting against the stop portion of the chassis. A resilient member is connected to the locking member and the top cover, for allowing the locking member to be offset, thereby the locking member riding over the stop portion and engaging therewith.

Other advantages and novel features will be drawn from the following detailed description of a preferred embodiment with attached drawings, in which:

### BRIEF DESCRIPTION OF THE DRAWINGS

FIG. 1 is an exploded, isometric view of a computer enclosure of a preferred embodiment of the present invention, the computer enclosure including a top cover, a chassis, a locking member, a driving member, and a pair of springs;

FIG. 2 is an isometric view of the top cover of FIG. 1, but viewed from another aspect;

FIG. 3 is an enlarged view of the locking member of FIG. 1;

FIG. 4 is an assembled view of the top cover, the locking member, the driving member, and the springs of FIG. 1, but viewed from another aspect;

FIG. 5 is an enlarged view of a marked circle portion V of FIG. 1; and

FIG. 6 is an enlarged view of a marked circle portion VI of FIG. 4.

### DETAILED DESCRIPTION OF PREFERRED EMBODIMENT

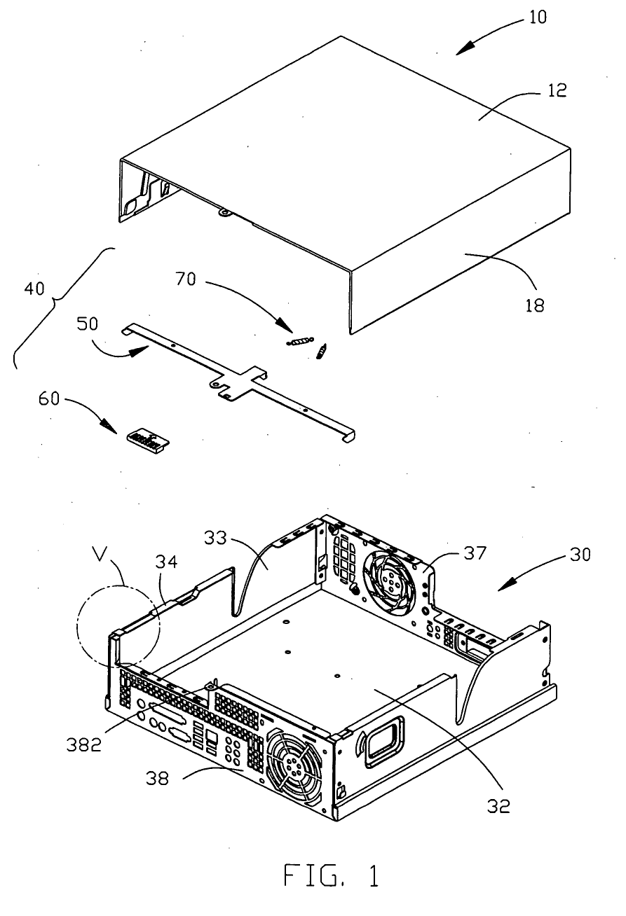

Referring to FIG. 1, an enclosure of an electronic device like a computer includes a top cover 10, a locking device 40, and a chassis 30.

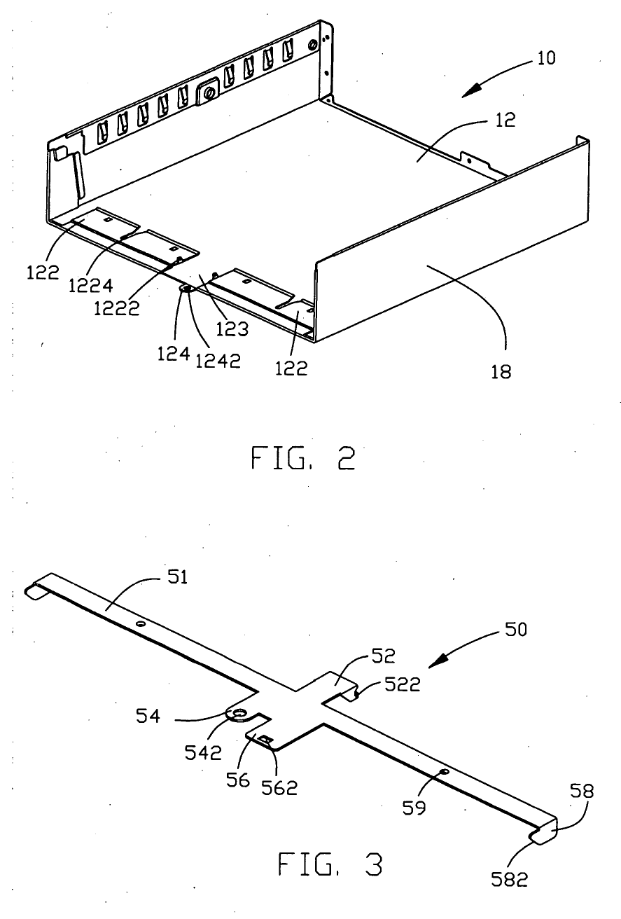

Referring also to FIG. 2, the top cover 10 includes a top panel 12, and a pair of side panels 18 perpendicular to and extending from opposite edges of the top panel 12. Two reinforcing clips 122 are bent back from an edge of the top panel 12 between the side panels 18, thereby forming a gap (not labeled) in the fold between each of the reinforcing clips 122 and the top panel 12. A cutout 123 is defined between the reinforcing clips 122. A locking tab 124 extends from the edge of the top panel 12 near the cutout 123. A locking hole 1242 is defined in the locking tab 124. A slot 1224 is defined in each reinforcing clip 122. A pair of bending tabs 1222 is bent up from adjacent edges of the reinforcing clips 122 respectively.

Referring also to FIG. 3, the locking device 40 includes a locking member 50, a driving member 60, and a pair of resilient members, such as springs 70. The locking member 50 includes a body 51. A lengthening portion 52 extends from a side edge of the body 51. A pair of hooks 522 is bent from corresponding edges of the lengthening portion 52. A locking tab 54, corresponding to the locking tab 124 of the top cover 10, and a driving portion 56 respectively extend from opposite sides of the lengthening portion 52 of the body 50. A locking hole 542 is defined in the locking tab 54. A bending clip 562 is bent down in the driving portion 56. Two protrusions 59 protrude down on each side portion of the body 51 respectively, corresponding to the slot 1224 of the top cover 10. A pair of locking portions 58 is bent down at opposite ends of the body 51 of the locking member 50 respectively. A slope 582 is formed at an end of each locking portion 58.

Referring also to FIG. 5, the chassis 30 includes a bottom wall 32, a pair of side walls 33 extruding from opposite edges of the bottom wall 32, a front wall 38, and a back wall 37. A locking tab 382 extends from the edge of the front wall 38 corresponding to the locking tab 54 of the locking member 50. A pair of flanges 34 is bent perpendicularly inward from the top edges of the side walls 33 respectively. Each flange 34 includes a stop portion 342 at the front end of the flange 34, and a contacting portion 346 is formed adjacent the stop portion 342 on one of the flanges 34. A slit 344 is defined between each flange 34 and corresponding side wall 33.

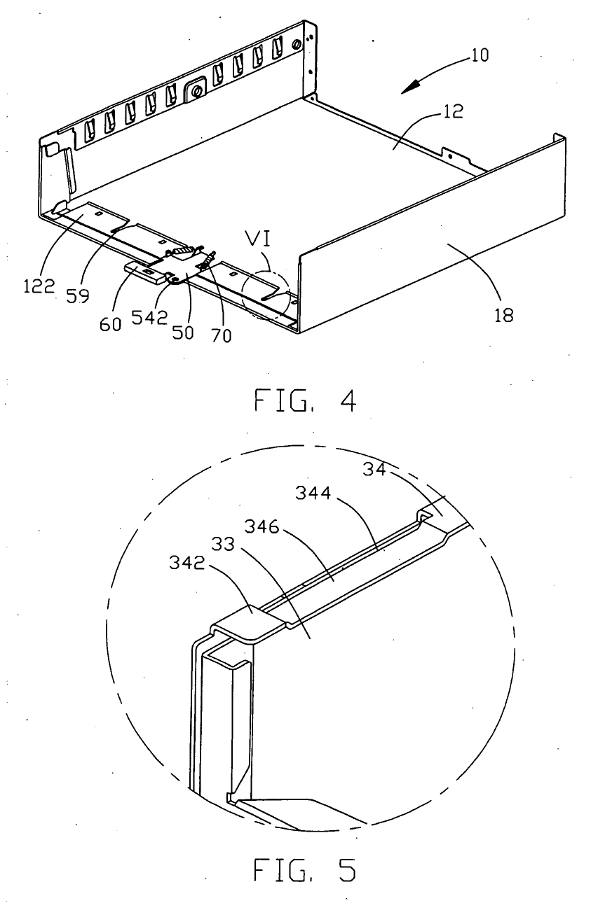

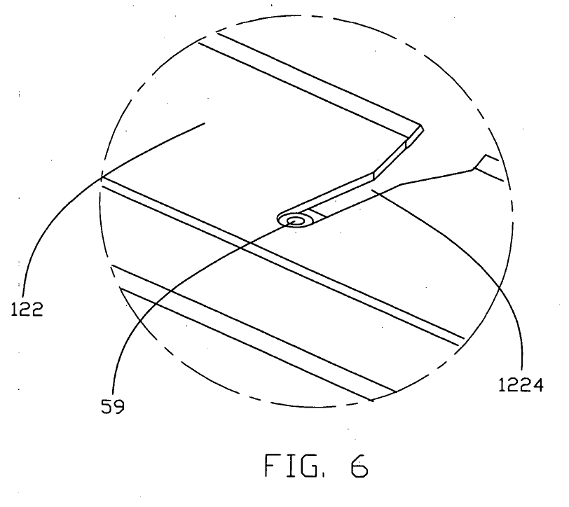

Referring also to FIGS. 4 and 5, in assembly of locking device 40, the locking member 50 is positioned between the reinforcing clips 122 and the top cover 10. The protrusions 59 are slidingly received by the corresponding slots 1224 of the reinforcing clips 122 of the top cover 10 respectively. The bending tabs 1222 are connected to the corresponding hooks 522 of the locking member 50 by the springs 70. The locking member 50 is secured within the gaps (not shown) of the folds between the reinforcing clips 122 and the top panel 12 by the pulling of the springs 70 elongating slightly, when each protrusion 59 of the locking member 50 is blocked by a distal end of the corresponding slot 1224 of the top cover 10. The driving member 60 is secured to the driving portion 56 with the bending clip 562 of the locking member 50.

In securing the top cover 10 to the chassis 30, the slope 582 of the locking member 50 abuts against the stop portions 342 of the chassis 30, thereby the locking member 50 being pushed inwardly until the locking portions 58 of the locking member 50 slide into the slits 344 of the chassis 30. Then the locking portions 58 of the locking member 50 slide back under the stop portion 342 of the chassis 30 and are blocked therebelow due to rebounding of the springs 70. Thus, the top cover 10 is secured to the chassis 30 by the locking device 40. The top cover 10 and the chassis 30 can be locked with a lock (not shown), and the lock is secured to the locking tab 124 of the top cover 10 and the locking tab 382 of the chassis 30.

In removing the top cover 10, the driving member 60 is pushed inwardly, the locking member 50 moves until its locking portions 58 are received by the corresponding slits 344 of the chassis 30 avoiding the stop portions 342 of the chassis 30 respectively. Then the top cover 10 is disengaged from the chassis 30.

It is to be understood, however, that even though numerous characteristics and advantages have been set forth in the foregoing description of a preferred embodiment, together with details of the structure and function of the preferred embodiment, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A computer enclosure, comprising:
a chassis, comprising a side wall, a stop portion horizontally formed on the side wall;
a top cover for covering the chassis; and
a locking member, slidably attached to the top cover, a locking portion vertically extending from the locking member corresponding to the stop portion of the chassis, a resilient member connected to the locking member and the top cover, for allowing the locking member to be offset, thereby the locking member riding over the stop portion and engaging therewith.

2. The computer enclosure as described in claim 1, wherein a flange is horizontally bent from the top edge of the side wall inwardly, the stop portion is formed at an end of the flange.

3. The computer enclosure as described in claim 2, wherein a slit is defined between the side wall of the chassis and the flange, for slidingly receiving the locking portion of the locking member.

4. The computer enclosure as described in claim 1, wherein a reinforcing clip is bent inward from an end of the top cover, for securing the locking member slidingly in the top cover.

5. The computer enclosure as described in claim 4, wherein a protrusion is formed on the locking member, and a slot corresponding to the protrusion is defined in the reinforcing clip.

6. The computer enclosure as described in claim 1, wherein a pair of locking clips extends from the top cover and the locking member respectively, for locking the locking member to the top cover, when the top cover is in the closed position.

7. The computer enclosure as described in claim 1, wherein the resilient member is a spring.

8. The computer enclosure as described in claim 1, wherein a driving member is secured to the locking member for driving the locking member slidingly in the top cover.

9. The computer enclosure as described in claim 1, wherein a slope is formed on the locking portion, for abutting against the stop portion of the chassis, while the locking member rides over the stop portion.

10. A computer enclosure, comprising:
a chassis, comprising at least a side wall, a stop portion formed on the side wall;
a top cover for covering the chassis; and
a locking member, slidably attached to the top cover, at least a locking portion extending from the locking member corresponding to the stop portion of the chassis, a slope is formed on the locking portion, for abutting against the stop portion of the chassis, at least a resilient member connected to the locking member and the top cover, for allowing the locking member to be offset, thereby the slope of the locking member abutting against the stop portion, and the locking member engaging with the stop portion of the chassis.

11. The computer enclosure as described in claim 10, whereas a flange is bent inward from the top edge of the side wall, the stop portion is formed at an end of the flange.

12. The computer enclosure as described in claim 11, wherein a slit is defined between the side wall of the chassis and the flange, for slidingly receiving the locking portion of the locking member.

13. The computer enclosure as described in claim 10, wherein at least a reinforcing clip is bent inward from an end of the top cover, for holding the locking member slidingly in the top cover.

14. The computer enclosure as described in claim 10, wherein at least a protrusion is formed on the locking member, and at least a slot corresponding to the protrusion is defined in the reinforcing clip.

15. The computer enclosure as described in claim 10, wherein a pair of locking tabs extend from the top cover and the locking member respectively, for keeping the locking member in place when the top cover is in the closed position.

16. The computer enclosure as described in claim 10, wherein the resilient member is a spring.

17. The computer enclosure as described in claim 10, wherein the locking portion is bent from a distal end of the locking member.

18. An electronic device comprising:
a chassis of said electronic device defining a space therein for accommodation of components of said electronic device, said chassis comprising two opposite sidewalls spaced from each other;
a cover of said electronic device removably attachable to said chassis so as to enclosing said space of said chassis therein together with said chassis; and
a locking member movably installable to a selective one of said chassis and said cover, said locking member comprising a locking portion extendable to each of said two sidewall and movable therealong, and resilient movement of said locking member capable of locking said cover to said chassis by means of said locking portion thereof and allowing removal of said cover from chassis by releasing said locking portion.

19. The electronic device as described in claim 18, wherein a slit is formed at the other of said chassis and said cover so as to receive said locking portion therein for said locking of said cover to said chassis.

20. The electronic device as described in claim 18, wherein at least one protrusion is formed at said locking member to be engagable with said selective one of said chassis and said cover so as to guide said resilient movement of said locking member.
